(19) United States
(12) Patent Application Publication
(10) Pub. No.: US 2025/0194143 A1
(43) Pub. Date: Jun. 12, 2025

(54) LATERALLY-DIFFUSED METAL-OXIDE SEMICONDUCTOR (LDMOS) DEVICE AND METHOD FOR FORMING THE SAME

(71) Applicant: TAIWAN SEMICONDUCTOR MANUFACTURING COMPANY LTD., HSINCHU (TW)

(72) Inventors: YU-YING LAI, CHANGHUA COUNTY (TW); PO-CHIH SU, NEW TAIPEI CITY (TW); PEI-LUN WANG, HSINCHU COUNTY (TW); RUEY-HSIN LIU, HSINCHU CITY (TW)

(21) Appl. No.: 18/530,248

(22) Filed: Dec. 6, 2023

(51) Int. Cl. H01L 29/78; H01L 29/40; H01L 29/66

(52) U.S. Cl. CPC H10D 30/65; H10D 30/0281; H10D 64/111

(57) ABSTRACT

An LDMOS device includes a gate structure, a multi-layered dielectric structure and at least a conductive field plate. The gate structure is disposed over a substrate and between a source region and a drain region. The multi-layered dielectric structure is disposed over the gate structure. The multi-layered dielectric structure includes a first dielectric layer in contact with the gate structure, and a second dielectric layer over the first dielectric layer. A thickness of the second dielectric layer is equal to or greater than a thickness of the first dielectric layer. The conductive field plate is disposed over the multi-layered dielectric structure.

### BACKGROUND

Laterally-diffused metal-oxide semiconductor (LDMOS) devices are planar double-diffused MOSFET (metal-oxide-semiconductor field-effect transistor) devices commonly used in amplifiers, including microwave power amplifiers, RF (radio frequency) power amplifiers and audio power amplifiers. Fabrication of LDMOS devices often includes a sequence of ion-implantation processes and annealing cycles in order to produce a doping profile sufficient to withstand electrical fields generated within the LDMOS device during operation.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart representing a method for forming an LDMOS device in accordance with aspects of the present disclosure.

FIGS. 2A to 2H are schematic drawings illustrating a semiconductor structure including an LDMOS device at various fabrication stages constructed in accordance with aspects of one or more embodiments of the present disclosure.

FIG. 3 is a flowchart representing a method for forming an LDMOS device in accordance with aspects of the present disclosure.

FIGS. 4A to 4G are schematic drawings illustrating a semiconductor structure including an LDMOS device at various fabrication stages constructed in accordance with aspects of one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat references numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any references to direction or orientation are merely intended for convenience of description and are not intended in any way to limit the scope of the present disclosure. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected” refer to a relationship wherein structures are secured or attached to one another either directly or indirectly through intervening structures, as well as both movable or rigid attachments or relationships, unless expressly described otherwise. Moreover, the features and benefits of the disclosure are illustrated by references to the embodiments. Accordingly, the disclosure expressly should not be limited to such embodiments illustrating some possible non-limiting combination of features that may exist alone or in other combinations of features, the scope of the disclosure being defined by the claims appended hereto.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

An LDMOS device used as a high voltage (HV) device often has field plates. The filed plates are conductive elements which are placed over a channel region in order to enhance a performance of the HV device by manipulating electric fields generated by a gate electrode of the HV device. In some embodiments, the LDMOS device may have the field plates disposed over the channel region and extending to a drift region, wherein the drift region is disposed between the channel region and a drain region of the LDMOS device. The field plates may reduce a peak electric field generated by the gate electrode. By manipulating the electric fields, the HV device can achieve higher breakdown voltages.

The field plates can be formed in a number of different ways. For example, the field plates may be formed by extending a conductive gate material from a gate electrode toward a drift region. Alternatively, the field plates may be formed by separated islands over the channel region and the drift region. Such configurations reduce gate-to-drain capacitance (C_{gd}), but placement of the field plates is often restricted by design rules. Further, such approach complicates a fabrication process and raises cost concerns. For example, a spacing distance is required between the field plates and a substrate (i.e., the channel region and the drift region), and such spacing distance can be achieved by disposing a thick dielectric layer between the field plate and an underlying gate structure. However, the thick dielectric layer may cause under-etching issue or incur a silicide issue in subsequent manufacturing processes. Such issues may lead to adverse impacts on other devices integrated with the LDMOS device.

The present disclosure therefore provides an LDMOS device having a field plate and methods for forming the same. In accordance with one embodiment of the method for forming the LDMOS device, a multi-layered dielectric structure is formed to separate the field plates from a substrate. The multi-layered dielectric structure may be formed by multiple depositions which can be interrupted by other operations. Further, the provided multi-layered dielectric structure enhances process flexibility and compatibility for forming the LDMOS device.

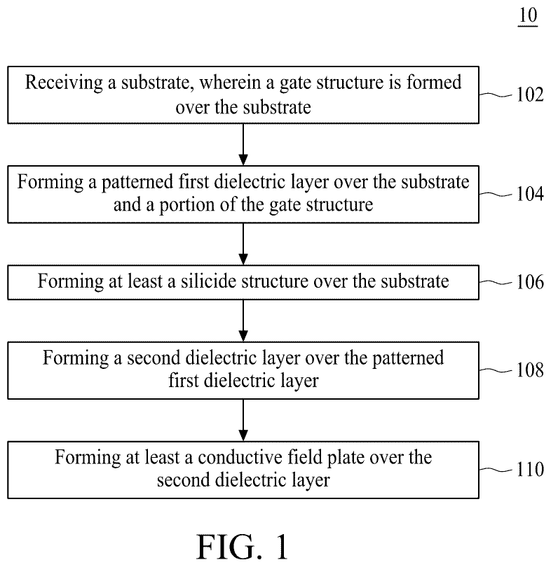

FIG. 1 is a flowchart representing a method for forming an LDMOS device 10 in accordance with aspects of the present disclosure. The method 10 includes a number of operations (102, 104, 106, 108 and 110). The method 10 will be further described in accordance with one or more embodiments. It should be noted that the operations of the method 10 may be rearranged or otherwise modified within the scope of the various aspects. It should be further noted that additional processes may be provided before, during, and after the method 10, and that some other processes may just be briefly described herein. Thus, other implementations are possible within the scope of the various aspects described herein.

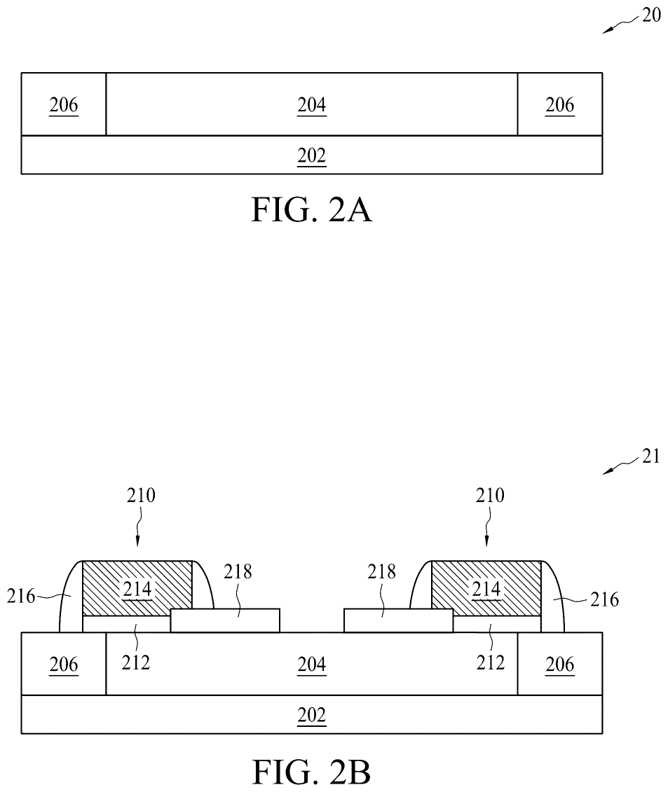

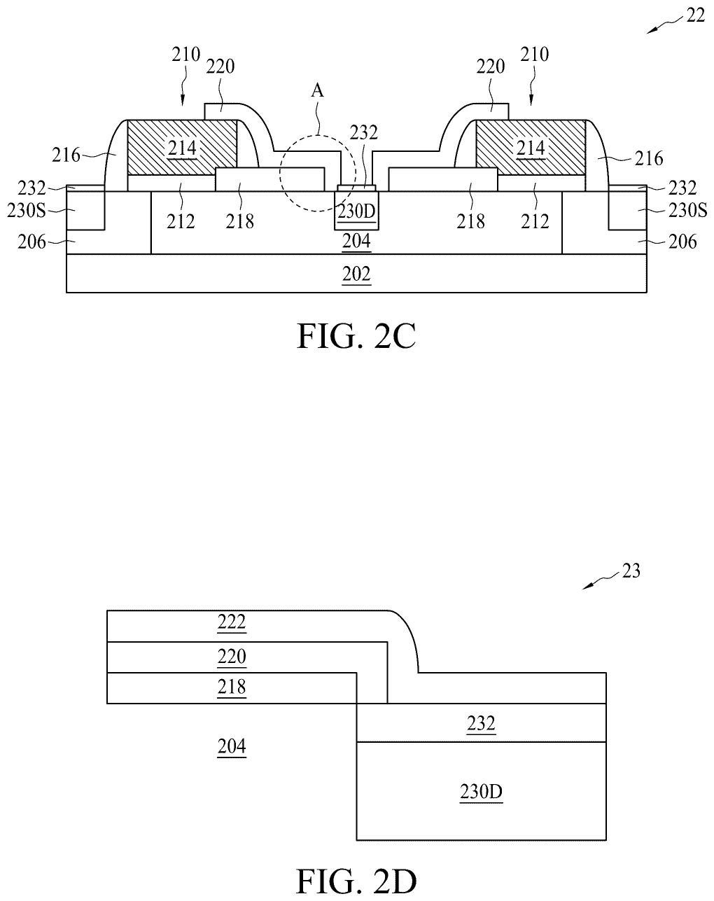

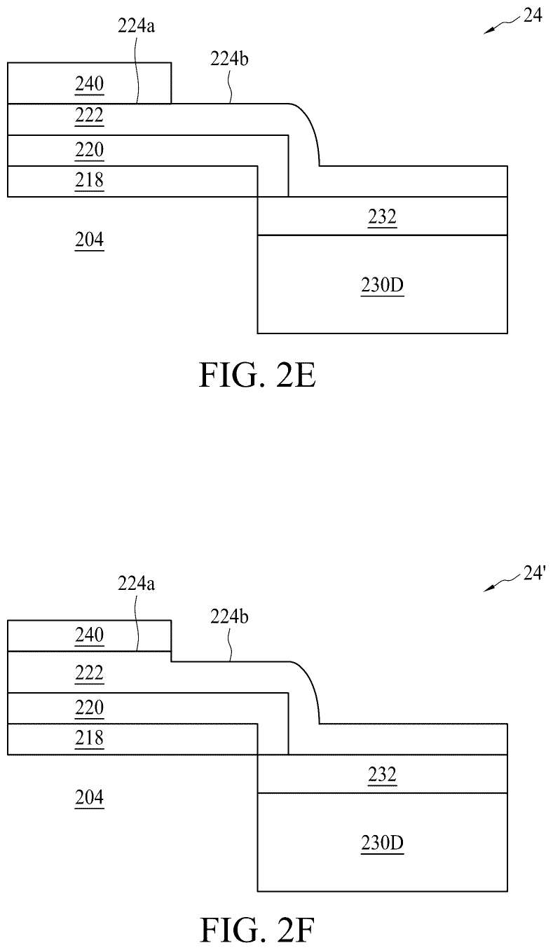

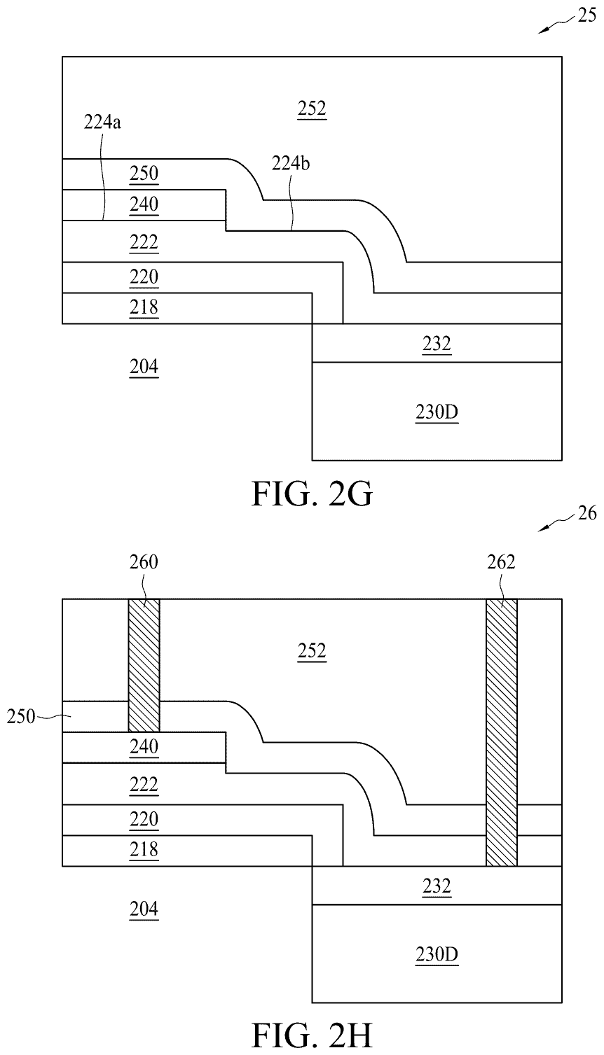

FIGS. 2A to 2H are schematic views illustrating a semiconductor structure including an LDMOS device at various fabrication stages constructed in accordance with aspects of one or more embodiments of the present disclosure. For example, FIG. 2A illustrates an intermediate semiconductor structure 20 in accordance with some embodiments corresponding to operation 102. Referring to FIG. 2A, in operation 102, a substrate 202 is received. The substrate 202 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate may include a SiGe alloy with a gradient Ge feature in which the Si/Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. Furthermore, the substrate 202 may be a semiconductor on insulator, such as silicon on insulator (SOI). In some embodiments, the substrate 202 may include a doped epitaxial layer or a buried layer. In some embodiments, the substrate 202 may have a multilayer structure, or the substrate 202 may include a multilayer compound semiconductor structure.

In some embodiments, the substrate 202 may be intrinsically doped to include a first doping type. Further, the substrate 202 may be selectively implanted using various implantations to form a plurality of doped regions. For example, the substrate 202 may be implanted to form a body region (not shown), a drift region 204 and a channel region 206. In some embodiments, the drift region 204 includes a second doping type with a concentration less than a concentration of a to-be-formed drain region in order to provide a greater resistance when the LDMOS device is operated at a high voltage. The first doping type and the second doping type are complementary to each other. In some embodiments, the first doping type is a p type, and the second doping type is an n type. In some embodiments, n-type dopants include arsenic (As), phosphorus (P), other group V elements, or any combination thereof. In some embodiments, p-type dopants include boron (B), other group III elements, or any combination thereof.

Referring to FIG. 2B, which illustrates an intermediate semiconductor structure 21 in accordance with some embodiments corresponding to operation 102, a gate structure 210 is formed over the substrate 202. The gate structure 210 may be formed to partially overlap the drift region 204 and partially overlap the channel region 206, as shown in FIG. 2B. The gate structure 210 may include a gate dielectric layer 212 and a gate electrode layer 214. The gate structure 210 may be formed by forming a dielectric material over the substrate 202, and by forming a semiconductor material over the dielectric material. In some embodiments, the dielectric material and the semiconductor material may be deposited by a vapor deposition technique. The dielectric material and the semiconductor material may be subsequently patterned and etched (e.g., as for a photoresist mask) to form the gate dielectric layer 212 and the gate electrode layer 214. In some embodiments, the gate structure 210 further includes sidewall spacers 216 formed on opposing sides of the gate electrode layer 214 by depositing a nitride- or oxide-based material onto the substrate 202, and selectively etching the nitride- or oxide-based material to form a nitride-based sidewall spacer 216 (e.g., comprising SiN) or an oxide-based sidewall spacer 216 (e.g., SiO₂, SiOC, etc.).

In some embodiments, the dielectric material used to form the gate dielectric layer 212 may include silicon oxide or a high-k gate dielectric material, and the semiconductor material used to form the gate electrode layer 214 may include, for example but not limited thereto, polysilicon, silicon-germanium, or the like. In some embodiments, the gate electrode layer 214 may further include at least one metallic material including elements and compounds such as Mo, Cu, W, Ti, Ta, TiN, TaN, NiSi, CoSi, or other suitable conductive materials known in the art. In some embodiments, the semiconductor material used to form the gate electrode layer 214 may be replaced with a work function metal layer that provides a metal gate with an n-type-metal work function or a p-type-metal work function. The p-type-metal work function materials include materials such as ruthenium, palladium, platinum, cobalt, nickel, conductive metal oxide, or other suitable materials. The n-type-metal work function materials include materials such as hafnium zirconium, titanium, tantalum, aluminum, metal carbides (e.g., hafnium carbide, zirconium carbide, titanium carbide, and aluminum carbide), aluminides, or other suitable materials.

Still referring to FIG. 2B, in some embodiments, a portion of the gate electrode 214 is formed over an isolation 218, and thus the gate electrode 214 is separated from the drift region 204 by the isolation 218 and the gate dielectric layer 212. The isolation 218 may be a field oxide (FOX) structure, but the disclosure is not limited thereto. In some embodiments, a thickness of the isolation 218 is greater than a thickness of the gate dielectric layer 212.

Referring to FIG. 2C, which illustrates an intermediate semiconductor structure 22 in accordance with some embodiments corresponding to operation 104 and operation 106, a patterned first dielectric layer 220 is formed over the substrate 202 and a portion of the gate structure 210. In some embodiments, the patterned first dielectric layer 220 may include a resist-protection oxide (RPO) layer, but the disclosure is not limited thereto. In some embodiments, a thickness of the patterned first dielectric layer 220 is less than approximately 250 angstroms, but the disclosure is not limited thereto. As shown in FIG. 2C, the patterned first dielectric layer 220 exposes a portion of the substrate 202 in the drift region 204, while the gate structure 210 exposes a portion of the substrate 202 in the channel region 206. In some embodiments, a source region 230S is formed in the portion of the substrate 202 exposed through the gate structure 210 in the channel region 206, and a drain region 230D is formed in the portion of the substrate 202 exposed through the patterned first dielectric layer 220 in the drift region 204. In some alternative embodiments, the source region 230S and the drain region 230D may be formed prior to the forming of the patterned first dielectric layer 220.

Additionally, the patterned first dielectric layer 220 covers a top surface of the isolation 218 and sidewalls of the isolation 218, as shown in FIG. 2C.

Still referring to FIG. 2C, in some embodiments, silicide structures 232 are formed over the source region 230S and the drain region 230D. It should be noted that operations for forming the semiconductor structure 22 may be integrated with operations for forming other semiconductor devices. For example, the forming of the gate structure 210, the forming of the source region 230S and the drain region 230D, and the forming of the silicide structures 232 may be used to form gate structures, source/drain regions and silicide structures of other devices. In such embodiments, the patterned first dielectric layer 220 may serve as a silicide blocking layer that prevent silicide structures from forming in unwanted places. Therefore, the thickness of the patterned first dielectric layer 220 may impact the forming of the silicide structure 232. It is known that the patterned first dielectric layer 220 is formed by depositing a dielectric layer (not shown) over the substrate 202 and the gate structure 210 followed by etching to remove portions of the dielectric layer. In some comparative approaches, a thicker patterned dielectric layer 220 suffers from under-etching, that is, portions of the dielectric layer that are supposed to be removed remain on the substrate 202. In such situation, the silicide structure 232 cannot be formed because the patterned dielectric layer 220 blocks the forming of the silicide structures. In contrast with the comparative approaches, because the thickness of the patterned first dielectric layer 220 is less than approximately 250 angstroms, the under-etching issue is mitigated, and the silicide structures 232 can be successfully formed.

Please refer to FIG. 2D, which is an enlarged drawing of a portion of an intermediate semiconductor structure 23 in accordance with operation 108. In some embodiments, FIG. 2D corresponds to circle A of the intermediate semiconductor structure 22 in FIG. 2C. It should be noted that the intermediate semiconductor structure 23 has a configuration that is symmetric about a central axis in the drain region 230D, as shown in FIG. 2C, but such details are omitted from FIG. 2D. In operation 108, a second dielectric layer 222 is formed over the patterned first dielectric layer 220. In some embodiments, the second dielectric layer 222 not only covers a top surface of the patterned first dielectric layer 220 and a sidewall of the patterned first dielectric layer 220, but also covers the silicide structures 232 over the source region 230S and the drain region 230D.

In some embodiments, the second dielectric layer 222 and the patterned first dielectric layer 220 can include a same material, such as RPO, but the disclosure is not limited thereto. A thickness of the second dielectric layer 222 is greater than the thickness of the patterned first dielectric layer 220. In some embodiments, a ratio of the thickness of the second dielectric layer 222 to the thickness of the patterned first dielectric layer 220 is between approximately 1 and approximately 1.5, but the disclosure is not limited thereto. In some embodiments, a sum of the thickness of the second dielectric layer 222 and the thickness of the patterned first dielectric layer 220 is between approximately 400 angstroms and approximately 1,300 angstroms, but the disclosure is not limited thereto.

Please refer to FIGS. 2E and 2F, which are enlarged drawings of portions of intermediate semiconductor structures 24 and 24′, respectively. In accordance with operation 110 in various embodiments, at least a conductive field plate 240 is formed over the second dielectric layer 222. As shown in FIGS. 2E and 2F, the conductive field plate 240 may be formed at a location overlying the drift region 204. Further, the conductive field plate 240 is separated from the substrate 202 (i.e., the drift region 204) and the gate structure 210 by the patterned first dielectric layer 220 and the second dielectric layer 222. A size of the conductive field plate 240 and a number of the conductive field plates 240 may vary depending on a size and other characteristics of the LDMOS device to be formed.

The forming of the conductive field plate 240 may include depositing a conductive material (not shown) over the second dielectric layer 222 and patterning the conductive material to form the conductive field plate 240. In some embodiments, the conductive field plate 240 covers a first top surface 224a of the second dielectric layer 222, while a second top surface 224b of the second dielectric layer 222 is exposed through the conductive field plate 240. In some embodiments, the first top surface 224a and the second top surface 224b of the second dielectric layer 222 of the intermediate semiconductor structure 24 form a flush surface, as shown in FIG. 2E. In other embodiments, the first top surface 224a and the second top surface 224b of the second dielectric layer 222 of the intermediate semiconductor structure 24′ form a step height, as shown in FIG. 2F. In some embodiments, an LDMOS device is obtained.

Upon receiving a bias voltage, the gate structure 210 is configured to generate an electric field that controls movement of charge carriers within the channel region 206 laterally disposed between the source region 230S and the drain region 230D. For example, during operation, a gate-source voltage (VGS) can be selectively applied to the gate structure 210 relative to the source region 230S, forming a conductive channel in the channel region 206. While the VGS is applied to form the conductive channel, a drain-to-source voltage (VDS) is applied to move charge carriers between the source region 230S and the drain region 230D. During operation, the conductive field plate 240 is configured to act upon the electric field generated by the gate structure 210. The conductive field plate 240 may be configured to change distribution of the electric field generated by the gate structure 210 in the drift region 204, which enhances an internal electric field of the drift region 204, thereby enhancing a breakdown voltage capability of the LDMOS device.

Referring to FIG. 2G, which is an enlarged drawing of a portion of an intermediate semiconductor structure 25 including the LDMOS device after the operation 110, an etch stop layer 250 such as a contact etch stop layer (CESL) is formed over the substrate 202, and an inter-layer dielectric (ILD) layer 252 is formed over the etch stop layer 250. In some embodiments, the etch stop layer 250 is conformally formed over the substrate 202. Further, the etch stop layer 250 is in contact with the conductive field plate 240 and the second top surface 224b of the second dielectric layer 222. In some embodiments, the etch stop layer 250 is separated from the patterned first dielectric layer 220 and the silicide structure 232 by the second dielectric layer 222. The ILD layer 252 is formed over the etch stop layer 250 and provides a flush or level surface for the intermediate semiconductor structure 25.

Referring to FIG. 2H, which is an enlarged drawing of a portion of an intermediate semiconductor structure 26 including the LDMOS device after the operation 110, in some embodiments, a plurality of connecting structures 260 and 262 are formed. Further, the connecting structures 260 and 262 penetrate the ILD layer 252, the etch stop layer 250, and the second dielectric layer 222. In some embodiments, the connecting structures 260 and 262 may electrically connect elements of the LDMOS device to a back-end-of-line (BEOL) metallization. For example, the connecting structure 260 may electrically connect the conductive field plate 240 to a BEOL metallization, and the connecting structure 262 may electrically connect the source region 230S or the drain region 230D to another BEOL metallization. The connecting structures 260 and 262 may include one or more of tungsten (W), tantalum-nitride (TaN), titanium (Ti), titanium-nitride (TiN), aluminum copper (AlCu), copper (Cu), and/or other similar conductive materials. In some embodiments, the conductive field plate 240 and the connecting structures 260 and 262 may include a same material, but the disclosure is not limited thereto.

Still referring to FIG. 2H, in accordance with the method 10 provided by the present disclosure, the thickness of the patterned first dielectric layer 220 is reduced such that the under-etch issue and the silicide blocking issue are mitigated. Further, the thickness of the second dielectric layer 222 is sufficient to enable the patterned first dielectric layer 220 and the second dielectric layer 222 to provide a suitable distance to separate the conductive field 240 and the drift region 204. Accordingly, process yield and device performance can be improved by the method 10.

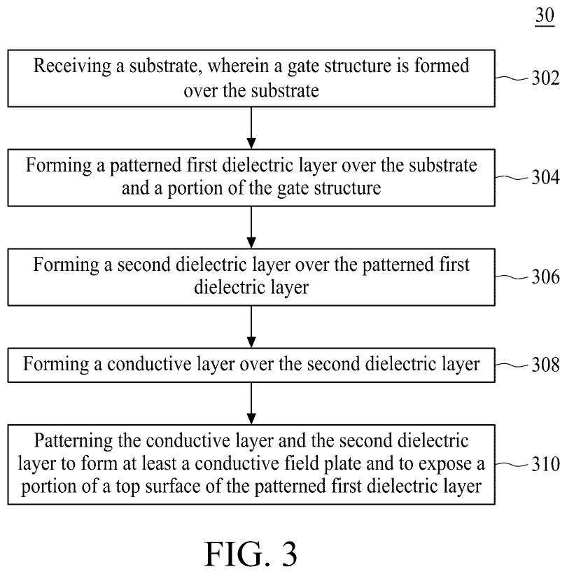

Please refer to FIG. 3, which is a flowchart representing a method for forming an LDMOS device 30 in accordance with aspects of the present disclosure. The method 30 includes a number of operations (302, 304, 306, 308 and 310). The method 30 will be further described in accordance with one or more embodiments. It should be noted that the operations of the method 30 may be rearranged or otherwise modified within the scope of the various aspects. It should be further noted that additional processes may be provided before, during, and after the method 30, and that some other processes may just be briefly described herein. Thus, other implementations are possible within the scope of the various aspects described herein.

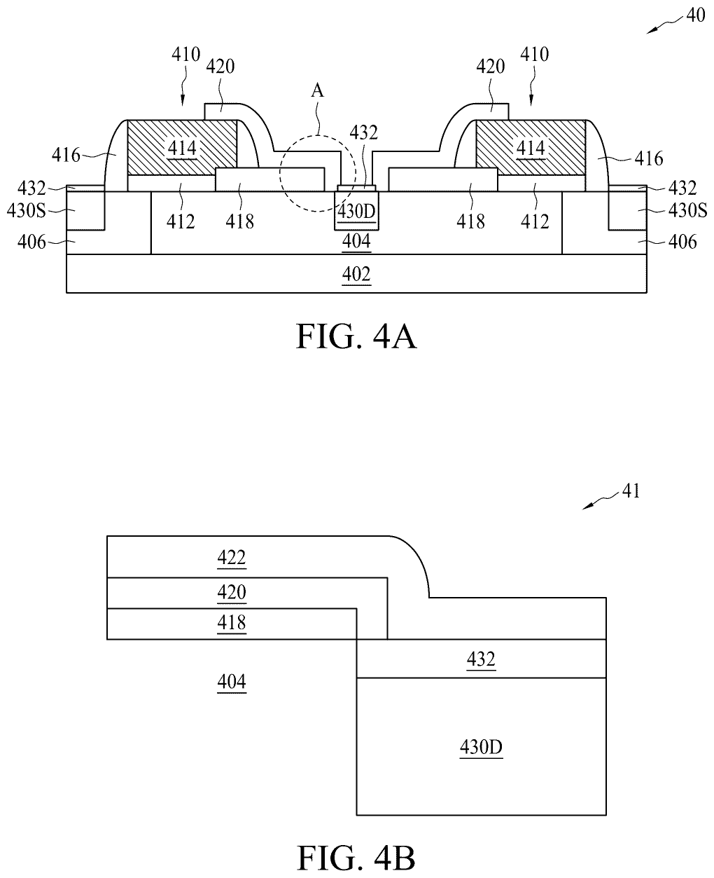

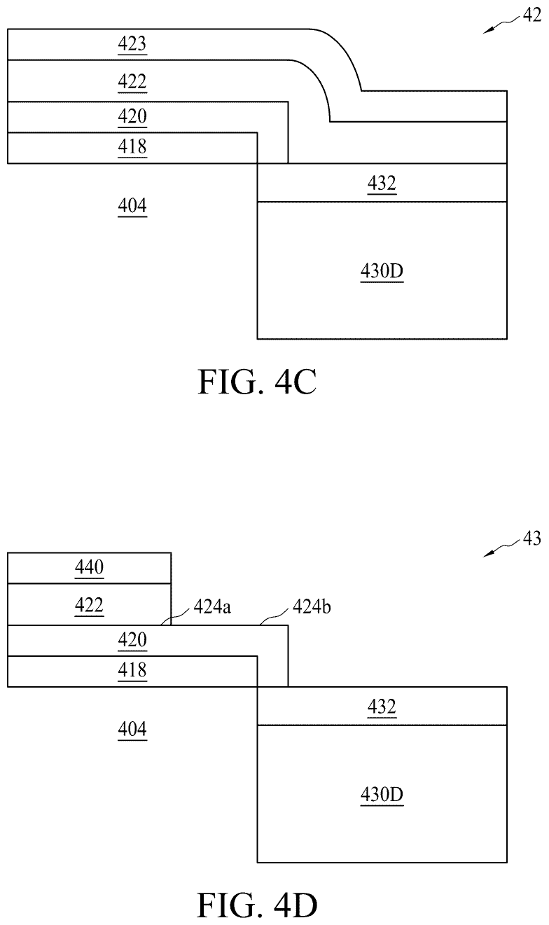

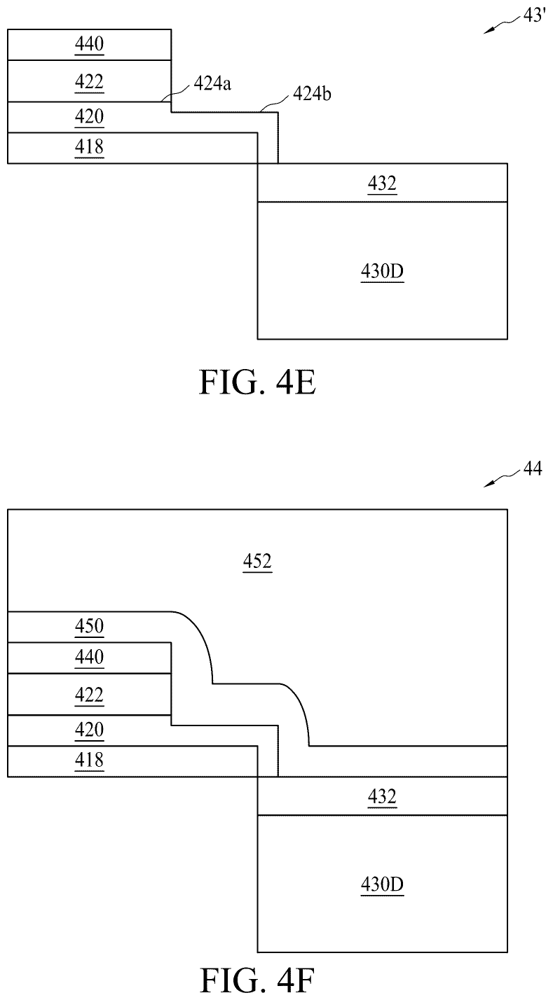

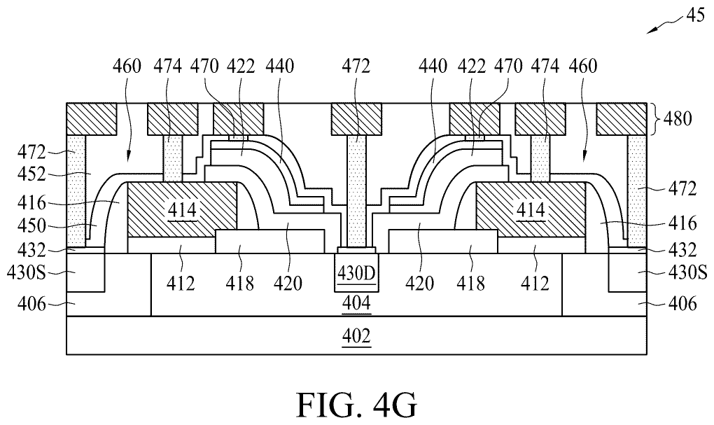

FIGS. 4A to 4G are schematic views illustrating a semiconductor structure including an LDMOS device at various fabrication stages constructed in accordance with aspects of one or more embodiments of the present disclosure. It should be noted that same elements in FIGS. 2A to 2H and FIGS. 4A to 4G may include same materials; therefore, repeated descriptions are omitted for brevity. Referring to FIG. 4A, which illustrates an intermediate semiconductor structure 40 in accordance with some embodiments corresponding to operation 302, a substrate 402 is received. In some embodiments, the substrate 402 may be intrinsically doped to include a first doping type. Further, the substrate 402 may be selectively implanted using various implantations to form a plurality of doped regions. For example, the substrate 402 may be implanted to form a body region (not shown), a drift region 404 and a channel region 406.

Still referring to FIG. 4A, in operation 302, a gate structure 410 is formed over the substrate 402. The gate structure 410 may be disposed to partially overlap the drift region 404 and partially overlap the channel region 406, as shown in FIG. 4A. The gate structure 410 may include a gate dielectric layer 412 and a gate electrode layer 414. In some embodiments, the gate structure 410 further includes sidewall spacers 416 formed on opposing sides of the gate electrode layer 414.

Further, as shown in FIG. 4A, a portion of the gate electrode layer 414 is formed over an isolation 418, and thus the gate electrode layer 414 is separated from the drift region 404 by the isolation 418 and the gate dielectric layer 412. The isolation 418 may be a field oxide (FOX) structure, but the disclosure is not limited thereto.

In operation 304, a patterned first dielectric layer 420 is formed over the substrate 402 and a portion of the gate structure 410. Additionally, the patterned first dielectric layer 420 covers a top surface of the isolation 418 and sidewalls of the isolation 418. In some embodiments, the patterned first dielectric layer 420 may include a resist-protection oxide (RPO) layer, but the disclosure is not limited thereto. In some embodiments, a thickness of the patterned first dielectric layer 420 is less than approximately 450 angstroms, but the disclosure is not limited thereto. As shown in FIG. 4A, the patterned first dielectric layer 420 exposes a portion of the substrate 402 in the drift region 404, while the gate structure 410 exposes a portion of the substrate 402 in the channel region 406. In some embodiments, a source region 430S is formed in the portion of the substrate 402 exposed through the gate structure 410 in the channel region 406, and a drain region 430D is formed in the portion of the substrate 402 exposed through the patterned first dielectric layer 420 in the drift region 404. In some alternative embodiments, the source region 430S and the drain region 430D may be formed prior to the forming of the patterned first dielectric layer 420.

Additionally, in some embodiments, silicide structures 432 are formed over the source region 430S and the drain region 430D. As mentioned above, the forming of the gate structure 410, the forming of the source region 430S and the drain region 430D, and the forming of the silicide structures 432 may be used to form gate structures, source/drain regions and silicide structures of other devices. In such embodiments, the patterned first dielectric layer 420 may serve as a silicide blocking layer for the other devices. Therefore, the thickness of the patterned first dielectric layer 420 may impact the forming of the silicide structure 420. For example, in some comparative approaches, a thicker patterned first dielectric layer 420 suffers from under-etching, and the patterned first dielectric layer 420 blocks the forming of the silicide structures. In contrast with such comparative approaches, because the thickness of the patterned first dielectric layer 420 is less than approximately 250 angstroms, the under-etching issue is mitigated, and the silicide structures 432 can be successfully formed.

Please refer to FIG. 4B, which is an enlarged drawing of a portion of an intermediate semiconductor structure 41 in accordance with operation 306. In some embodiments, FIG. 4B corresponds to circle A of the intermediate semiconductor structure 40 in FIG. 4A. It should be noted that the intermediate semiconductor structure 41 has a configuration that is symmetric about a central axis in the drain region 430D, as shown in FIG. 4A, but such details are omitted from FIG. 4B. In operation 306, a second dielectric layer 422 is formed over the patterned first dielectric layer 420. In some embodiments, the second dielectric layer 422 is conformally formed over the patterned first dielectric layer 420 and the substrate 402. In some embodiments, the second dielectric layer 422 not only covers a top surface of the patterned first dielectric layer 420 and a sidewall of the patterned first dielectric layer 420, but also covers the silicide structures 432 over the source region 430S and the drain region 430D.

In some embodiments, the second dielectric layer 422 and the patterned first dielectric layer 420 can include a same material, such as RPO, but the disclosure is not limited thereto. A thickness of the second dielectric layer 422 is greater than the thickness of the patterned first dielectric layer 420. In some embodiments, a ratio of the thickness of the second dielectric layer 422 to the thickness of the patterned first dielectric layer 420 is between approximately 1 and approximately 1.5. In some embodiments, a sum of the thickness of the second dielectric layer 422 and the thickness of the patterned first dielectric layer 420 is between approximately 400 angstroms and approximately 1,300 angstroms, but the disclosure is not limited thereto.

Please refer to FIG. 4C, which is an enlarged drawing of a portion of an intermediate semiconductor structure 42 in accordance with operation 308. In operation 308, a conductive layer 423 is formed over the second dielectric layer 422.

Please refer to FIGS. 4D and 4E, which are enlarged drawings of portions of intermediate semiconductor structures 43 and 43′ in accordance with operation 310 in various embodiments. In operation 310, the conductive layer 423 and the second dielectric layer 422 are patterned. Accordingly, at least a conductive field plate 440 is formed over the patterned second dielectric layer 422. As shown in FIGS. 4D and 4E, the conductive field plate 440 may be disposed at a location overlying the drift region 404. Further, the conductive field plate 440 is separated from the gate structure 410 by the patterned first and second dielectric layers 420 and 422. A size of the conductive field plate 440 and a number of the conductive field plates 440 may vary depending on a size and other characteristics of the LDMOS device to be formed. In some embodiments, a sidewall of the conductive field plate 440 and a sidewall of the patterned second dielectric layer 422 are aligned.

In some embodiments, the conductive field plate 440 and the patterned second dielectric layer 422 cover a first top surface 424a of the patterned first dielectric layer 420, while a second top surface 424b of the patterned first dielectric layer 420 is exposed through the conductive field plate 440 and the patterned second dielectric layer 422. In some embodiments, the first top surface 424a and the second top surface 424b of the patterned first dielectric layer 420 of the intermediate semiconductor structure 43 form a flush surface, as shown in FIG. 4D. In other embodiments, the first top surface 424a and the second top surface 424b of the patterned first dielectric layer 420 of the intermediate semiconductor structure 43′ form a step height, as shown in FIG. 4E. In some embodiments, an LDMOS device 460 (shown in FIG. 4G) is obtained.

As mentioned above, upon receiving a bias voltage, the gate structure 410 is configured to generate an electric field that controls movement of charge carriers within the channel region 406 laterally disposed between the source region 430S and the drain region 430D. For example, during operation, a gate-source voltage (VGS) can be selectively applied to the gate structure 410 relative to the source region 430S, forming a conductive channel in the channel region 406. While the VGS is applied to form the conductive channel, a drain-to-source voltage (VDS) is applied to move charge carriers between the source region 430S and the drain region 430D. During operation, the conductive field plate 440 is configured to act upon the electric field generated by the gate structure 410. The conductive field plate 440 may be configured to change distribution of the electric field generated by the gate structure 410 in the drift region 404, which enhances an internal electric field of the drift region 404, thereby enhancing a breakdown voltage capability of the LDMOS device 460.

Referring to FIG. 4F, which is an enlarged drawing of a portion of an intermediate semiconductor structure 44 including the LDMOS device after the operation 310, an etch stop layer 450 such as a CESL is formed over the substrate 402, and an ILD layer 452 is formed over the etch stop layer 450. In some embodiments, the etch stop layer 450 is conformally formed over the substrate 402. Further, the etch stop layer 450 is in contact with the conductive field plate 440, the patterned second dielectric layer 422, and the patterned first dielectric layer 420. In some embodiments, the etch stop layer 450 is in contact with a top surface of the conductive field plate 440, the sidewall of the conductive field plate 440, the sidewall of the patterned second dielectric layer 422, the second top surface 424b of the patterned first dielectric layer 420, and the silicide structure 432 (or the drain region 430D). The ILD layer 452 is formed over the etch stop layer 450 and provides a flush or level surface for the intermediate semiconductor structure 44.

Please refer to FIG. 4G, which is a schematic drawing of a semiconductor structure 45 including the LDMOS device 460 after the operation 310. In some embodiments, a plurality of connecting structures 470 to 474 are formed. Further, the connecting structures 470 to 474 penetrate the ILD layer 452 and the etch stop layer 450. In some embodiments, the connecting structures 470 to 474 may electrically connect elements of the LDMOS device 460 to a back-end-of-line (BEOL) metallization 480. For example, the connecting structure 470 may electrically connect the conductive field plate 440 to one of the BEOL metallizations 480, the connecting structure 472 may electrically connect the source region 430S and/or the drain region 430D to another BEOL metallization 480, and the connecting structure 474 may electrically connect the gate structure 410 to still another BEOL metallization 480. In some embodiments, the conductive field plate 440 and the connecting structures 470 to 474 may include a same material, but the disclosure is not limited thereto.

Still referring to FIG. 4G, in accordance with the method 30 provided by the present disclosure, the thickness of the patterned first dielectric layer 420 is reduced such that the under-etch issue and the silicide blocking issue are mitigated. Further, the thickness of the patterned second dielectric layer 422 is sufficient to enable the patterned first dielectric layer 420 and the second dielectric layer 422 to provide a suitable distance to separate the conductive field 440 from the drift region 404. Further, because the second dielectric layer 422 is patterned simultaneously with the patterning of the conductive field plate 440, portions of the second dielectric layer 422 are removed from where the connecting structures 470 are to 474 to be formed. Therefore, a possibility that the second dielectric layer 422 may be under-etched and may thus obstruct the forming of the connecting structures 470 to 474 can be mitigated. Accordingly, process yield and device performance can be improved by the method 30.

Accordingly, the present disclosure provides methods for forming an LDMOS device having a conductive field plate. The conductive field plate is separated from a substrate by a multi-layered dielectric structure including two dielectric layers separately formed. Such approaches help to mitigate under-etching and silicide blocking issues by forming a first dielectric layer having a reduced thickness prior to forming of silicide structures. Therefore, a process yield is improved. Further, the methods help to provide sufficient distance between the conductive field plate and the substrate by forming a second dielectric layer having a thickness greater than that of the first dielectric layer. Therefore, the device performance is further improved.

In accordance with one embodiment of the present disclosure, an LDMOS device is provided. The LDMOS device includes a gate structure, a multi-layered dielectric structure and at least a conductive field plate. The gate structure is disposed over a substrate and between a source region and a drain region. The multi-layered dielectric structure is disposed over the gate structure. The multi-layered dielectric structure includes a first dielectric layer in contact with the gate structure, and a second dielectric layer over the first dielectric layer. A thickness of the second dielectric layer is equal to or greater than a thickness of the first dielectric layer. The conductive field plate is disposed over the multi-layered dielectric structure.

In accordance with one embodiment of the present disclosure, a method for forming an LDMOS device is provided. The method includes following operations. A substrate is received. A gate structure is formed over the substrate. A patterned first dielectric layer is formed over the substrate and a portion of the gate structure. At least a silicide structure is formed over the substrate. A second dielectric layer is formed over the patterned first dielectric layer. At least a conductive field plate is formed over the second dielectric layer.

In accordance with one embodiment of the present disclosure, a method for forming an LDMOS device is provided. The method includes following operations. A substrate is received. A gate structure is formed over the substrate. A patterned first dielectric layer is formed over the substrate and a portion of the gate structure. A second dielectric layer is formed over the patterned first dielectric layer. A conductive layer is formed over the second dielectric layer. The conductive layer and the second dielectric layer are patterned to form at least a conductive field plate and to expose a portion of a top surface of patterned first dielectric layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A laterally-diffused metal-oxide semiconductor (LDMOS) device comprising:
a gate structure disposed over a substrate and between a source region and a drain region;
a multi-layered dielectric structure disposed over the gate structure, wherein the multi-layered dielectric structure comprises:
a first dielectric layer in contact with the gate structure; and
a second dielectric layer over the first dielectric layer, wherein a thickness of the second dielectric layer is equal to or greater than a thickness of the first dielectric layer; and
at least a conductive field plate over the multi-layered dielectric structure.

2. The LDMOS device of claim 1, further comprising:
an etch stop layer disposed over the conductive field plate, the multi-layered dielectric structure and the drain region;
an inter-layer dielectric (ILD) layer disposed over the etch stop layer; and
a connecting structure coupled to the drain region.

3. The LDMOS device of claim 2, wherein the connecting structure penetrates the etch stop layer and is in contact with the drain region.

4. The LDMOS device of claim 3, wherein a portion of a top surface of the first dielectric layer is in contact with the etch stop layer.

5. The LDMOS device of claim 2, wherein the connecting structure penetrates the etch stop layer and the second dielectric layer of the multi-layered dielectric structure, and is in contact with the drain region.

6. The LDMOS device of claim 5, wherein the first dielectric layer is separated from the etch stop layer by the second dielectric layer.

7. The LDMOS device of claim 1, wherein the first dielectric layer has a top surface and a sidewall, and the second dielectric layer covers the top surface and the sidewall of the first dielectric layer.

8. The LDMOS device of claim 1, wherein the second dielectric layer covers a first top surface of the first dielectric layer, and exposes a second top surface of the first dielectric layer.

9. The LDMOS device of claim 8, wherein the first top surface and the second top surface of the first dielectric layer form a step height.

10. The LDMOS device of claim 1, wherein a sidewall of the second dielectric layer and a sidewall of the conductive field plate are aligned.

11. A method for forming an LDMOS device, comprising:
receiving a substrate, wherein a gate structure is formed over the substrate;
forming a patterned first dielectric layer over the substrate and a portion of the gate structure;
forming at least a silicide structure over the substrate;
forming a second dielectric layer over the patterned first dielectric layer; and
forming at least a conductive field plate over the second dielectric layer.

12. The method of claim 11, further comprising forming a source region and a drain region after the forming of the patterned first dielectric layer.

13. The method of claim 11, further comprising forming an etch stop layer and an ILD layer over the substrate after the forming of the conductive field plate.

14. The method of claim 13, further comprising forming a connecting structure penetrating the ILD layer, the etch stop layer and the second dielectric layer.

15. The method of claim 13, wherein the first dielectric layer is separated from the etch stop layer by the second dielectric layer.

16. A method for forming an LDMOS device, comprising:
receiving a substrate, wherein a gate structure is formed over the substrate;
forming a patterned first dielectric layer over the substrate and a portion of the gate structure;
forming a second dielectric layer over the patterned first dielectric layer;
forming a conductive layer over the second dielectric layer; and
patterning the conductive layer and the second dielectric layer to form at least a conductive field plate and to expose a portion of a top surface of the patterned first dielectric layer.

17. The method of claim 16, further comprising forming a silicide structure prior to the forming of the second dielectric layer.

18. The method of claim 16, wherein the patterning of the conductive layer and the second dielectric layer exposes the drain region.

19. The method of claim 18, further comprising forming an etch stop layer and an ILD layer over the substrate after the forming of the conductive field plate, wherein the etch stop layer is in contact with a drain region.

20. The method of claim 19, further comprising forming a connecting structure penetrating the ILD layer and the etch stop layer, wherein the connecting structure is in contact with the drain region.
